(19) United States
(12) Patent Application Publication
(10) Pub. No.: US 2012/0234370 A1
(43) Pub. Date: Sep. 20, 2012

(54) LIGHT ENERGY CONCENTRATOR

(76) Inventors: Frank Bretl, Corvallis, OR (US); John P. Whitlock, Lebanon, OR (US); Stephan R. Clark, Albany, OR (US)

(21) Appl. No.: 13/051,322

(22) Filed: Mar. 18, 2011

(51) Int. Cl. H01L 31/052; H01L 31/0232

(52) U.S. Cl. 136/246; 136/259

(57) ABSTRACT

Apparatus and methods are provided for use with solar energy. An upper surface and a lower surface disposed there beneath have respective parabolic curvatures. The upper surface includes a coating and concentrates a first spectral portion of incident light upon a first target. The lower surface includes a reflective coating and concentrates a second spectral portion of the incident light upon a second target distinct from the first target. The first and second targets can be photovoltaic cells that are optimized for the respective photonic energies concentrated thereon.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Solar energy devices and apparatus make use of incident sunlight to heat water or other fluids, for direct conversion to electrical energy, and so on. Improvements in solar energy capture, energy transfer or conversion efficiency within such devices and systems is constantly sought after. The present teachings address the foregoing and other concerns.

### BRIEF DESCRIPTION OF THE DRAWINGS

The present embodiments will now be described, by way of example, with reference to the accompanying drawings, in which:

FIG. 1 is a schematic view of an apparatus including upper and lower parabolic surfaces according to one example of the present teachings;

FIG. 2 is flow diagram of a method according to another example of the present teachings;

FIG. 3A is an isometric view of a spectral splitter and concentrator in a disassembled state according to an example of the present teachings;

FIG. 3B is an isometric view of the spectral splitter and concentrator of FIG. 3A in an assembled state;

FIG. 4A is an isometric view of a spectral splitter and concentrator in a disassembled state according to another example of the present teachings;

FIG. 4B is an isometric view of the spectral splitter and concentrator of FIG. 4B in an assembled state and performing normal operations;

FIG. 5 is a flow diagram of a method according to an example of the present teachings;

FIG. 6 is an isometric view of an array of spectral splitters and concentrators according to another example of the present teachings.

### DETAILED DESCRIPTION

### Introduction

Apparatus and methods are provided for use with solar energy. An upper surface and a lower surface have respective parabolic curvatures. The lower surface is disposed beneath and spaced apart from the upper surface. The upper surface includes a surface coating and concentrates a first spectral portion of incident light upon a first target. The lower surface includes a reflective coating and concentrates a second spectral portion of the incident light upon a second target distinct from the first target. The first and second targets can be photovoltaic cells or other entities that are optimized for the respective spectral energies concentrated thereon.

In one example, an apparatus includes an upper surface to concentrate a first spectral content of incident light onto a first target and to pass a second spectral content of the incident light through the upper surface. The apparatus also includes a lower surface beneath and spaced apart from the upper surface. The lower surface to concentrate the second spectral content of incident light onto a second target. The first spectral content is defined by photonic energies different than that of the second spectral content.

In another example, a photovoltaic energy device includes a first photovoltaic cell, and a second photovoltaic cell spaced apart from the first photovoltaic cell. The photovoltaic energy device also includes an upper parabolic surface including a coating material to concentrate some incident light energy onto the first photovoltaic cell and to permit some of the light energy to pass there through. The upper parabolic surface is thermoformed from plastic. The photovoltaic energy device further includes a lower parabolic surface including a reflective material to concentrate the light energy passing through the upper parabolic surface onto the second photovoltaic cell. The lower parabolic surface is also thermoformed from plastic.

In yet another example, a method includes concentrating a first energy content of incident sunlight onto a first photovoltaic cell using a first parabolic structure. The method also includes passing a second energy content of the incident sunlight through the first parabolic structure. The method further includes concentrating the second energy content onto a second photovoltaic cell using a second parabolic structure.

### Illustrative Apparatus

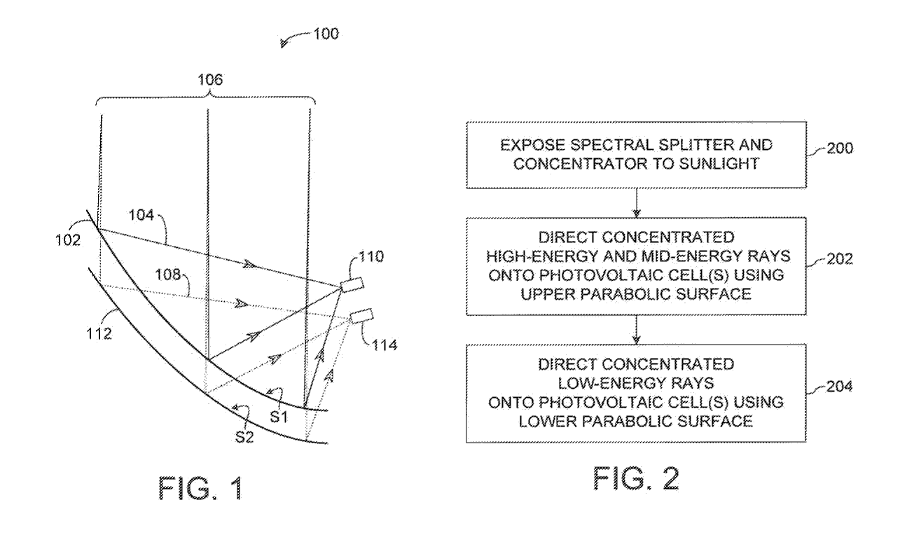

Reference is now directed to FIG. 1 which depicts a schematic view of an apparatus 10. The apparatus 100 is illustrative and non-limiting with respect to the present teachings. Thus, other apparatuses, devices or systems can be configured and/or operated in accordance with the present teachings. The apparatus 100 is also referred to as a spectral splitter and concentrator (SSC) 100 for purposes of the present teachings.

The apparatus 100 includes an upper surface 102. The upper surface 102 is formed from a transparent material such as, for non-limiting example, glass, plastic, and so on. In one example, the upper surface 102 is formed from polyethylene naphthalate (PEN), having a thickness of about two-hundred micrometers (1 micrometer=10⁻⁶ meters), by way of thermoforming techniques. Other materials or thicknesses can also be used. The upper surface 102 is depicted edge-on and is defined by a parabolic cross-sectional curvature (or a segment of a parabola). Thus, the upper surface 102 is also referred to as an upper parabolic surface 102.

The upper parabolic surface 102 includes a surface coating or treatment “S1” that reflects a first spectral portion or energy band 104 of incident light rays 106, while passing a second spectral portion or energy band 108 there through. In one example, such surface treatment S1 is defined by a respective layers of titanium dioxide (TiO₂) and silicon dioxide (SiO₂). In another example, the surface treatment S1 is defined by respective layers of niobium dioxide (NiO₂) and silicon dioxide (SiO₂). Other suitable surface treatments can also be used. The first spectral portion 104 is depicted in solid line format and the second spectral portion 108 is depicted in dotted line format so as to distinguish one from another.

In one example, such incident light rays 106 are defined by or include solar energy or solar radiation. The upper parabolic surface 102 is therefore reflective (or essentially so) with respect to the first spectral portion 104, and transparent (or essentially so) with respect to the second spectral portion 108. The upper parabolic surface 102 can also be referred to as having the characteristics of a bandpass filter with respect to incident photonic energy. In one example, the first spectral portion 104 is of greater photonic energy content (i.e., is shorter in wavelength) than the second spectral portion 108. In another example, the first spectral portion 104 is of lesser photonic energy content (i.e., is longer in wavelength) than the second spectral portion 108.

The upper parabolic surface 102 is configured to concentrate the first spectral portion 104 onto a target 110. In one example, the target 110 is defined by a photovoltaic (PV) cell or a plurality of such PV cells to provide electrical energy in response to photonic energy. In one example, such a photovoltaic cell 110 is defined by a gallium arsenide (GaAs) cell, available from Emcore Corporation, Albuquerque, N. Mex., USA. In another example, the photovoltaic cell 110 is defined by a silicon cell, available from Emcore Corporation. Such photovoltaic cell(s) 110 can be defined by performance characteristics consistent with or matched to the first spectral portion 104. That is, the photovoltaic cell(s) 110 are substantially optimized with respect to the photonic energies of the first spectral portion 104.

The apparatus 100 includes a lower surface 112. The lower surface 112 is formed from a transparent material such as, for non-limiting example, glass, plastic, and so on. In one example, the lower surface 112 is produced from PEN by way of thermoforming techniques. The lower surface 112 is defined by a parabolic cross-sectional curvature (or a segment of a parabola). Thus, the lower surface 112 is also referred to as a lower parabolic surface 102.

The lower parabolic surface 112 is disposed generally beneath and spaced apart from the upper parabolic surface 102. The lower parabolic surface 112 is positioned to receive the second spectral portion 108 that passes through the upper parabolic surface 102. The lower parabolic surface includes a reflective surface coating or treatment “S2” that reflects the second spectral portion 108, which is concentrated onto a target 114. In one example, such surface treatment S2 is defined by a layer of silver (Ag) protected with an over-coating of silicon dioxide (SiO₂). In another example, a layer of aluminum (Al) is used, protected by an over-coating of silicon dioxide (SiO₂). Other suitable surface treatments can also be used. The target 114 is distinct and spaced apart from the target 112.

In one example, the target 114 is defined by a photovoltaic cell or a plurality of such photovoltaic cells to provide electrical energy in response to photonic energy. In one example, such a photovoltaic cell 114 is defined by a high-efficiency silicon and germanium (Si/Ge) cell, developed by the University of Delaware, USA. In such an example, the photovoltaic cell(s) 114 are defined by performance characteristics consistent with or matched to the second spectral portion 108. That is, the photovoltaic cell(s) 110 are substantially optimized with respect to the photonic energies of the second spectral portion 108.

The Table 1 below provides illustrative and non-limiting details for a spectral splitter and concentrator 100 according to the present teachings. Other examples having respectively varying characteristics and details can also be used:

TABLE 1
Illustrative SSC 100

| Element | Material | Comments/Other |
|---|---|---|
| Surface 102 | PEN | 200 μm Thick |
| Coating S1 | TiO₂/SiO₂ | Multilayer dichroic |
| PV Cell 110 | GaAs or Si | Emcore Corp./Univ of Delaware |
| Surface 112 | PEN | 200 μm Thick |
| Coating S2 | Ag/SiO₂ | Protected metal film |
| PV Cell 114 | Si/Ge or GaAs | Univ. of Delaware/Emcore Corp |

### Illustrative Method

Reference is now made to FIG. 2, which depicts a flow diagram of a method according to the present teachings. The method of FIG. 2 includes particular operations and order of execution. However, other methods including other operations, omitting one or more of the depicted operations, and/or proceeding in other orders of execution can also be used according to the present teachings. Thus, the method of FIG. 2 is illustrative and non-limiting in nature. Reference is made to FIG. 1 in the interest of understanding FIG. 2.

At 200, a spectral splitter and concentrator is exposed to sunlight. For purposes of a present example, the SSC 100 is exposed to incident solar radiation 106.

At 202, concentrated high-energy and mid-energy rays are directed onto photovoltaic cell(s) using an upper parabolic surface. For purposes of the present example, incident sunlight 106 includes a first spectral portion or content 104 comprised of high- and mid-energy photons. This first spectral portion 104 is concentrated onto a photovoltaic cell 110 that is disposed proximate to the SSC 100. In response, the photovoltaic cell 110 provides an electromotive force (i.e., voltage).

At 204, concentrated low-energy rays are directed onto photovoltaic cell(s) using a lower parabolic surface. For purposes of the present example, incident sunlight 106 includes a second spectral portion or content 108 comprised of low-energy photons. This second spectral portion 108 passes through the upper parabolic surface 102 and is incident upon the lower parabolic surface 112. The second spectral portion 108 is then concentrated onto a photovoltaic cell 114 disposed proximate to the SSC 100. In response, the photovoltaic cell 114 provides an electrical voltage.

The method of FIG. 2 depicts normal operations of a spectral splitter and concentrator according to the present teachings. In general, and without limitation, such an SSC separates or “splits” incident photonic energy into at least two distinct energy bands or spectra. Such splitting is performed by way of the upper parabolic surface by virtue of a surface coating born by a transparent material. The high- and mid-energy photons are then reflected and concentrated, by virtue of the parabolic curvature, onto a first target such as a photovoltaic cell or array thereof.

The low-energy photons pass through the upper parabolic surface and are incident upon a lower parabolic surface. The lower parabolic surface reflects and concentrates these low-energy photons onto a second target such as a photovoltaic cell or array of such PV cells. The lower parabolic surface includes reflective surface coating or treatment, but can be formed from the same or similar material as the upper parabolic surface.

The present teachings contemplate various embodiments having two or more parabolic surfaces, disposed in a generally stacked or nested arrangement. In one example, a spectral splitter and concentrator includes three distinct parabolic surfaces each having surface coatings so that three distinct energy spectra are concentrated onto corresponding targets. Other embodiments can also be used.

### Illustrative Spectral Splitter and Concentrator

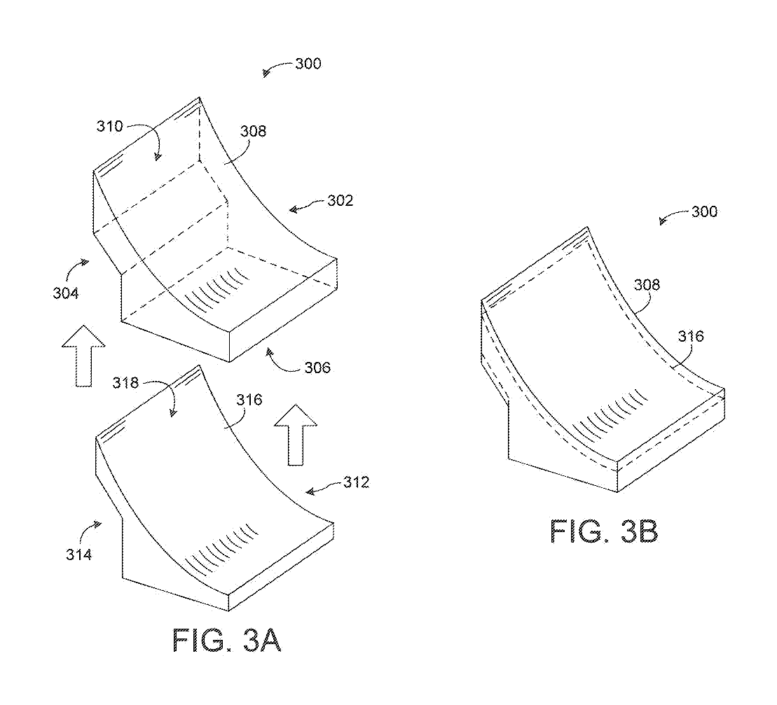

Attention is now directed to FIG. 3A, which an isometric view of a spectral splitter and concentrator (SSC) 300 in a disassembled state, according to the present teachings. The SSC 300 is illustrative and non-limiting with respect to the present teachings. Thus, other SSC's, devices and systems can be configured and/or operated in accordance with the present teachings.

The SSC 300 includes an upper portion 302. In one example, the upper portion 302 is formed of transparent thermoplastic by way of thermoforming techniques. Other materials or forming techniques can also be used. The upper portion 302 includes a box-like structure 304 such that an internal cavity is defined. The upper portion 302 defines an open bottom aperture 306 permitting access to the internal cavity.

The upper portion 302 also includes a surface portion 308 defined by a parabolic curvature in at least one cross-sectional aspect. The surface portion 308 is therefore also referred to as an upper parabolic surface 308. The upper parabolic surface 308 includes a surface material or treatment 310. The surface treatment 310 is such that a first spectra or energy band of incident light (e.g., 106) is reflected away from the upper parabolic surface 308. Such reflected first spectral portion is concentrated at a point or region proximate to the SSC 300. Additionally, a second spectra or energy band of incident light passes through the surface treatment 310 and the transparent material of parabolic surface 308.

The SSC 300 also includes a lower portion 312. In one example, the lower portion 312 is formed of transparent thermoplastic by way of thermoforming techniques. Other materials or forming techniques can also be used. The lower portion 312 includes a box-like structure 314. Such box-like structure 314 can be hollow or solid in accordance with varying examples of the present teachings.

The lower portion 312 also includes a surface portion 316 defined by a parabolic curvature in at least one cross-sectional aspect. The surface portion 316 is therefore also referred to as a lower parabolic surface 316. The lower parabolic surface 316 includes a surface material or treatment 318. The surface material 318 is such that a second spectra or energy band is reflected away from the lower parabolic surface 316 and concentrated at a point or region proximate to the SSC 300. The lower portion 312 is configured (dimensioned or constructed) to be received within the internal cavity of the upper portion 102 by way of the bottom aperture 306.

Attention is now directed to FIG. 3B, an isometric view of the spectral splitter and concentrator (SSC) 300 in an assembled state. The assembled SSC 300 has the lower portion 312 fully received within the upper portion 302. As such, the upper parabolic surface 308 and the lower parabolic surface 316 are in a spaced, substantially parallel orientation to each other.

Sunlight energy (e.g., 106) incident upon the SSC 300 is split by way of the upper parabolic surface 308 such that relatively greater energy photons are concentrated in or toward a first region in space. Lower energy photons of the sunlight pass through the upper parabolic surface 308 and are incident upon the lower parabolic surface 316. These relatively lower energy photons are then concentrated in or toward a second region in space. In this way, sunlight energy is spectrally separated or divided in accordance with photonic energy levels into two distinct bands and concentrated in respective areas of space relatively near to the SSC 300.

### Another Illustrative Spectral Splitter and Concentrator

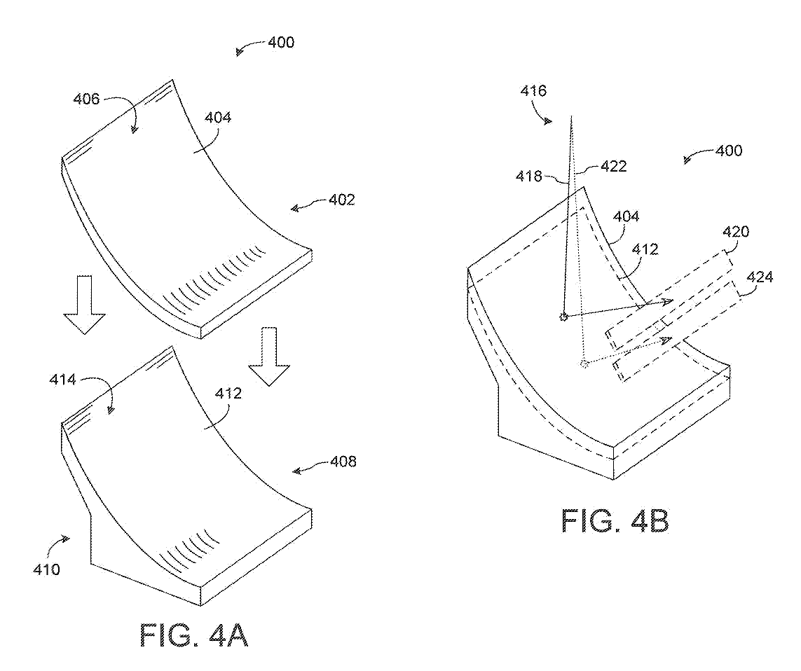

Attention is now directed to FIG. 4A, which an isometric view of a spectral splitter and concentrator (SSC) 400 in a disassembled state, according to the present teachings. The SSC 400 is illustrative and non-limiting with respect to the present teachings. Thus, other SSC's, devices and systems can be configured and/or operated in accordance with the present teachings.

The SSC 400 includes an upper portion 402. In one example, the upper portion 402 is formed of transparent thermoplastic by way of thermoforming techniques. Other materials or forming techniques can also be used. The upper portion 402 includes a surface portion 404 defined by a parabolic curvature in at least one cross-sectional aspect. The surface portion 404 is therefore also referred to as an upper parabolic surface 404.

The upper parabolic surface 404 includes a surface material or treatment 406. The surface treatment 406 is such that a first spectra or energy band of incident light (e.g., 106) is reflected away from the upper parabolic surface 404. Such reflected first spectral portion is concentrated at a point or region proximate to the SSC 400. Additionally, a second spectra or energy band of incident light passes through the surface treatment 406 and the transparent material of the upper portion 402.

The SSC 400 also includes a lower portion 408. In one example, the lower portion 408 is formed of transparent thermoplastic by way of thermoforming techniques. Other materials or forming techniques can also be used. The lower portion 408 includes by a box-like structure 410. Such box-like structure 410 can be hollow or solid in accordance with varying examples of the present teachings.

The lower portion 408 also includes a surface portion 412 defined by a parabolic curvature in at least one cross-sectional aspect. The surface portion 412 is therefore also referred to as a lower parabolic surface 412. The lower parabolic surface 412 includes a surface material or treatment 414. The surface material 414 is such that a second spectra or energy band is reflected away from the lower parabolic surface 412 and concentrated at a point or region proximate to the SSC 400. The lower portion 408 is configured (dimensioned or constructed) to be joined or bonded to the upper portion 402 by way of an adhesive, mechanical fasteners, or so on.

Attention is now directed to FIG. 4B, an isometric view depicting the SSC 400 in an assembled state and performing normal operations. The assembled SSC 400 has the lower portion 408 joined to and supportive of the upper portion 402. As such, the upper parabolic surface 404 and the lower parabolic surface 412 are in a spaced, substantially parallel orientation to each other.

Sunlight energy 416 incident upon the SSC 400 is split by way of the upper parabolic surface 404 such that relatively greater energy photons 418 are concentrated in or toward a first region in space, depicted by target 420. Lower energy photons 422 of the sunlight 416 pass through the upper parabolic surface 404 and are incident upon the lower parabolic surface 412.

The relatively lower energy photons 422 are then concentrated in or toward a second region in space, depicted by target 424. In this way, sunlight energy 416 is spectrally separated or divided in accordance with photonic energy levels into two distinct bands 418 and 422, respectively, and concentrated in respective areas of space proximate the SSC 400. It is noted that the SSC 300 performs-normal operations analogous to those of the SSC 400.

### Illustrative Method

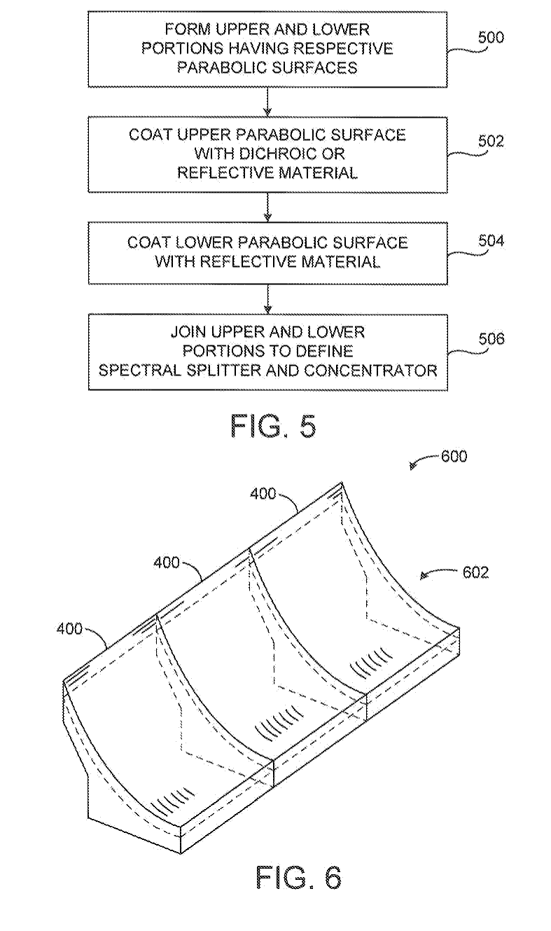

Reference is now made to FIG. 5, which depicts a flow diagram of a method according to the present teachings. The method of FIG. 5 includes particular operations and order of execution. However, other methods including other operations, omitting one or more of the depicted operations, and/or proceeding in other orders of execution can also be used according to the present teachings. Thus, the method of FIG. 5 is illustrative and non-limiting in nature. Reference is made to FIGS. 3A-3B in the interest of understanding FIG. 5.

At 500, upper and lower portions are formed having respective parabolic surfaces. For purposes of a present example, an upper portion (i.e., element) 302 and a lower portion 312 are formed from thermoplastic using thermoforming. Both upper and lower portions 302 and 312 are formed of transparent thermoplastic material and are substantially rigid in a final state. The upper portion 302 includes a parabolic surface 308—that is, a surface or face 308 defined by a parabolic or segmental-parabolic cross-sectional curvature. In turn, the lower portion 312 includes a parabolic surface 316.

At 502, the upper parabolic surface is coated with a dichroic or reflective material. For purposes of the present example, the parabolic surface 308 of the upper portion 302 is coated throughout with a material 310 that passes light of relatively lower photonic energies, while reflecting light of relatively high- or mid-range photonic energies. In one example, the material 310 is defined by multilayer dichroic coating (e.g., TiO₂/SiO₂, NbO/SiO₂, or another High/Low index stack). Other suitable materials 310 can also be used. The material (or materials) can be deposited by way of sputtering, evaporation, or another suitable thin-film deposition method.

At 504, the lower parabolic surface is coated with a reflective material. For purposes of the present example, the parabolic surface 316 of the lower portion 312 is coated throughout with a material 318 that reflects light incident there upon. In one example, the material 318 is defined by either a silver (Ag) or aluminum (Al) coating protected by on over-coating of silicon dioxide (SiO₂). Other suitable materials 318 can also be used. Sputtering or other suitable techniques can be used to deposit the material 318.

At 506, the upper and lower portions are joined to define a spectral splitter and concentrator. For purposes of the present example, the lower portion 312 is received within the upper portion 302 such that an assembled unit is defined. The unit is a spectral splitter and concentrator 300 in accordance with the present teachings. The SSC 300 is configured to operate substantially equivalently to the spectral splitter and concentrator 400.

### Illustrative Array of Devices

Reference is now made to FIG. 6, which depict an array 600 of respective spectral splitters and concentrators. The array 600 is illustrative and non-limiting with respect to the present teachings. Other devices or systems can be configured and/or operated in accordance with the present teachings.

The array 600 includes a total of three spectral splitter and concentrator devices 400 arranged in a side-by-side configuration, such that a row 602 is defined. The array 600 is configured to concentrate light energy onto one or more respective targets. Such light energy (e.g., 106) is typically defined by sunlight and includes respective high- and mid-energy photons (e.g., 104), and low-energy photons (e.g., 108), respectively. These respective spectra or energy bands of the sunlight are separated and concentrated onto distinct regions in space (i.e., targets) proximate to the array 600.

Thus, the present teachings contemplate arrays of spectral splitter and concentrator devices. An array can be arranged and defined by one or more rows having any suitable number of SSC devices per row. Such arrays normally operate to capture sunlight incident upon areas of any suitable scale (e.g., square inches, square meters, and so on) and to concentrate respective energy bands within that sunlight onto corresponding targets. Such targets can be photovoltaic cells, heat-transfer piping, hot water generation apparatus, and so on.

In general, and without limitation, the present teachings contemplate various spectral splitters and concentrators. A device or apparatus is constructed having at least two parabolic surfaces disposed in a spaced, overlying adjacency. At least the uppermost parabolic surface is formed from a transparent material. Thermoplastic and other suitable materials can be used. The parabolic surfaces are then subject to respective surface treatments or materials by way of coating, vapor deposition, and so on.

An upper parabolic surface is treated such that a first energy content of incident light is reflected there from and concentrated in a proximate region of space. The upper parabolic surface treatment also permits a second energy content of the incident light to pass there though. In one example, the first energy content is relatively greater than the second energy content. In a complimentary example, the first energy content is lesser than the second energy content.

A lower parabolic surface is disposed to receive the second energy content passing through the upper parabolic surface. The lower parabolic surface is treated to reflect this second energy content and concentrate it in a proximate region of space. The first and second energy spectra are concentrated in different regions spaced apart from one another. Distinct targets are or can be placed to receive the concentrated spectral energies from the upper and lower parabolic surfaces.

Targets can be selected or configured for the particular spectral content concentrated there on. For one non-limiting example, a photovoltaic cell having performance characteristics consistent with high- or mid-energy photons is disposed to receive energy from an upper parabolic surface. In furtherance of the present example, a photovoltaic cell having performance characteristics in accordance with low-energy photons is positioned to receive energy from a lower parabolic surface. Arrays of such spectral splitters and concentrators can be used to capture and concentrate solar energy incident upon any suitable area.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
An upper surface to concentrate a first spectral content of incident light onto to a first target and to pass a second spectral content of the incident light through the upper surface; and
a lower surface beneath and spaced apart from the upper surface, the lower surface to concentrate the second spectral content of incident light onto to a second target, the first spectral content defined by photonic energies different than that of the second spectral content.

2. The apparatus according to claim 1, at least the upper surface or the lower surface being thermoformed from a transparent plastic.

3. The apparatus according to claim 1, the upper surface bearing at least a dichroic material, the lower surface bearing at least a reflective material.

4. The apparatus according to claim 1, the upper surface and the lower surface having respective cross-sectional shapes defined by at least a segment of a parabola.

5. The apparatus according to claim 1, the upper surface and the lower surface being portions of an entity formed by joining at least two distinct pieces.

6. The apparatus according to claim 1, the first target including at least one photovoltaic cell.

7. The apparatus according to claim 6, the at least one photovoltaic cell having performance characteristics in accordance with the first spectral content.

8. The apparatus according to claim 1, the second target including at least one photovoltaic cell.

9. The apparatus according to claim 8, the at least one photovoltaic cell having performance characteristics in accordance with the second spectral content.

10. The apparatus according to claim 1, the upper surface being a portion of a box-like structure, the lower surface being received within the box-like structure.

11. A photovoltaic energy device, comprising:
a first photovoltaic cell;
a second photovoltaic cell spaced apart from the first photovoltaic cell;
an upper parabolic surface including a coating material to concentrate some incident light energy onto the first photovoltaic cell and to permit some of the light energy to pass there through, the upper parabolic surface thermoformed from a plastic material; and
a lower parabolic surface including a reflective material to concentrate the light energy passing through the upper parabolic surface onto the second photovoltaic cell, the lower parabolic surface thermoformed from a plastic material.

12. The photovoltaic energy device according to claim 11, the upper parabolic surface and the lower parabolic surface to concentrate light energy of a first spectra and a second spectra, respectively, the first spectra characterized by an photonic energy content different than that of the second spectra.

13. The photovoltaic energy device according to claim 11, the first photovoltaic cell defined by performance characteristics distinct from those of the second photovoltaic cell.

14. The photovoltaic energy device according to claim 11, the coating material of the upper parabolic surface including at least a dichroic material, the dichroic material including at least titanium dioxide, niobium dioxide, or silicon dioxide.

15. A method, comprising:
concentrating a first photonic energy content of incident sunlight onto a first photovoltaic cell using a first parabolic structure;
passing a second photonic energy content of the incident sunlight through the first parabolic structure; and
concentrating the second photonic energy content onto a second photovoltaic cell using a second parabolic structure.
